(19) United States
(12) Patent Application Publication
(10) Pub. No.: US 2025/0315797 A1
(43) Pub. Date: Oct. 9, 2025

(54) MAINTENANCE AND INSPECTION APPARATUS

(71) Applicant: TOYOTA JIDOSHA KABUSHIKI KAISHA, Toyota-shi (JP)

(72) Inventors: Tomoyuki KUBOTA, Susono-shi (JP); Yoshihiro SAKAYANAGI, Mishima-shi (JP)

(73) Assignee: TOYOTA JIDOSHA KABUSHIKI KAISHA, Toyota-shi (JP)

(21) Appl. No.: 19/051,438

(22) Filed: Feb. 12, 2025

(30) Foreign Application Priority Data
Apr. 8, 2024 (JP) 2024-062361

(51) Int. Cl. G06Q 10/20; G01R 31/40; H02J 7/00

(52) U.S. Cl. CPC G06Q 10/20; G01R 31/40; H02J 7/0047

(57) ABSTRACT

A maintenance and inspection apparatus for performing maintenance and inspection in VPP, includes a processor to select a charger/discharger to be maintained and inspected from among a plurality of chargers and dischargers based on a discharge execution list, in which a time elapsed from a previous discharge with respect to each of the chargers and dischargers, and a charger/discharger state list, which indicates an available state for each of the chargers and dischargers, and update, after charging/discharging by the charger/discharger to be maintained and inspected, updates the discharge execution list by adding an execution result of test charge/discharge by the charger/discharger to be maintained and inspected.

### CROSS-REFERENCE TO RELATED APPLICATION(S)

The present application claims priority to and incorporates by reference the entire contents of Japanese Patent Application No. 2024-062361 filed in Japan on Apr. 8, 2024.

### BACKGROUND

The present disclosure relates to a maintenance and inspection apparatus.

Japanese Laid-open Patent Publication No. 2023-71463 discloses a technique for controlling the planning of maintenance and inspection of a plurality of storage battery units connected to a power system. In this technique, the amount of power generation generated by a power generating facility connected to a power system is estimated, and based on this estimated amount of electric power, the maintenance schedule of multiple storage battery units is generated.

### SUMMARY

There is a need for provide a maintenance and inspection apparatus that can reliably perform maintenance and inspections for a predetermined period.

According to an embodiment, a maintenance and inspection apparatus for performing maintenance and inspection in VPP, includes a processor to select a charger/discharger to be maintained and inspected from among a plurality of chargers and dischargers based on a discharge execution list, in which a time elapsed from a previous discharge with respect to each of the chargers and dischargers, and a charger/discharger state list, which indicates an available state for each of the chargers and dischargers, and update, after charging/discharging by the charger/discharger to be maintained and inspected, updates the discharge execution list by adding an execution result of test charge/discharge by the charger/discharger to be maintained and inspected.

### BRIEF DESCRIPTION OF THE DRAWINGS

FIG. 1 is a schematic configuration diagram of a virtual power plant to which a maintenance and inspection system according to an embodiment is applied;

FIG. 2 is a block diagram illustrating the functional configuration of a maintenance inspection apparatus;

FIG. 3 is a diagram illustrating an example of a discharge execution list recorded by a discharge execution list recording unit provided in the maintenance inspection apparatus;

FIG. 4 is a diagram illustrating an example of a maintenance and inspection list recorded by a maintenance and inspection list recording unit provided in the maintenance inspection apparatus;

FIG. 5 is a diagram illustrating an example of a charger/discharger state list recorded by a charger/discharger status list recording unit provided in the maintenance inspection apparatus;

FIG. 6 is a flowchart illustrating an outline of a process that is executed by the maintenance and inspection apparatus according to an embodiment;

FIG. 7 is a diagram illustrating an example of the discharge execution list after update;

FIG. 8 is a diagram illustrating an example of the maintenance and inspection list after test execution;

FIG. 9 is a diagram illustrating an example of the charger/discharger state list after the test execution; and

FIG. 10 is a flowchart illustrating an outline of a process that is executed by a maintenance and inspection apparatus according to a modified example.

### DETAILED DESCRIPTION

In Japanese Laid-open Patent Publication No. 2023-71463, since generating a maintenance or inspection schedule based on the power generation amount of the estimated power generation facility, if the state of low power generation is continued, the opportunity for maintenance or inspection may be limited, and it may not be reliably performed in a predetermined period of time.

Hereinafter, a maintenance and inspection system including a maintenance and inspection apparatus according to an embodiment of the present disclosure will be described with reference to the drawings. Note that the components in the following embodiments include those which can be substituted and easily by those skilled in the art, or those which are substantially the same. Further, the drawings referred to in the following description are only schematically illustrating the shape, size, and positional relationship to the extent that the contents of the present disclosure can be understood. In other words, the present disclosure is not limited only to the shape, size, and positional relationship exemplified in each of the figures.

### Configuration of the Maintenance and Inspection System

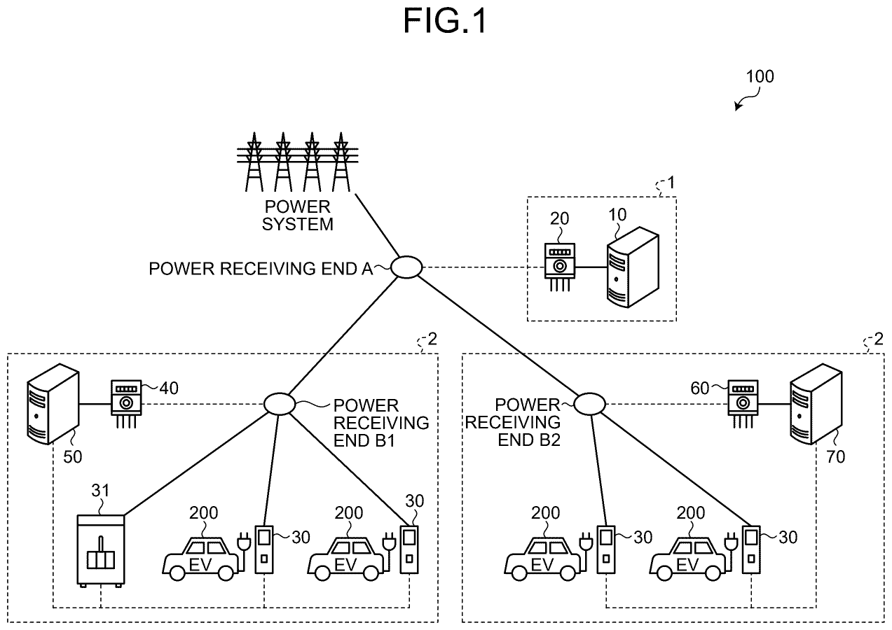

FIG. 1 is a schematic configuration diagram of a virtual power plant (VPP) to which a maintenance and inspection system according to an embodiment is applied. A maintenance inspection system 100 illustrated in FIG. 1 includes a first power receiving group 1 connected to a power receiving end A which is connected via a power transmission line to the power system for transmitting the power generated by the power plant or the like, a second power receiving group 2 including a power receiving end B1 connected to the power receiving end A via a power transmission, and a third power receiving group 3 including a power receiving end B2 connected to the power receiving end A via a power transmission line.

The power receiving end A, after converting the voltage of the power supplied from the power system into a predetermined voltage, supplies the power to the power receiving end B1 and the power receiving end B2 through the transmission lines. The power receiving end A, for example, may be a high-voltage substation or the like.

The first power receiving group 1 performs maintenance and inspection of the second power receiving group 2 and the third power receiving group 3 through the power receiving end A. The first power receiving group 1 includes a maintenance and inspection apparatus 10, and a power meter 20.

The maintenance and inspection apparatus 10 selects a discharge device to be maintained and inspected according to the maintenance and inspection list of a charger/discharger to be maintained and updates the result of performing charging and discharging for inspection for the selected charger/discharger by writing in the discharge execution list. The detailed configuration of the maintenance and inspection apparatus 10 will be described later.

The power meter 20 measures the charge and discharge at the power receiving end A, and outputs the measurement result to the maintenance and inspection apparatus 10. In one embodiment, in order that that the charging and discharging at the power receiving end A is 0, the maintenance and inspection apparatus 10 performs control so that the discharging power of the power receiving end B1 is equal to the received power of the power receiving end B2.

The second power receiving group 2 includes a power receiving end B1, a plurality of chargers and dischargers 30, a stationary battery 31, a power meter 40, and a control device 50.

The power receiving end B1 converts a power supplied from the power receiving end A into a predetermined voltage, and supplies the converted power to the plurality of chargers and dischargers 30 and the stationary battery 31. The power receiving end B1 is configured using a transformer or the like.

Each of the plurality of chargers and dischargers 30 is a charging station or the like, and is connected to an electric vehicle(s) 200 to charge a battery of the electric vehicle 200 by using the power supplied from the power receiving end B1. Each of the plurality of chargers and dischargers 30 also discharges the power supplied from the battery of the connected electric vehicle 200 to the power receiving end B1. Incidentally, the electric vehicle 200, that is a Electric Vehicle (EV) having a battery, may be a Hybrid Vehicle (HV) or a Fuel Cell Electric Vehicle (FCEV) or the like.

The stationary battery 31 is configured, for example, using a lithium-ion battery or the like, while storing the power supplied from the power receiving end B1, under the control of the control device 50, discharging the stored power to the power receiving end B1.

The power meter 40 measures the charge and discharge of the power receiving end B1, and outputs the measurement result to the control device 50.

The control device 50 controls the charging and discharging of the second power receiving group 2 under the control of the maintenance and inspection apparatus 10. The control device 50 is implemented using a memory and a processor having hardware. The hardware may be, for example, memories, a Central Processing Unit (CPU), a Digital Signal Processor (DSP) and a Field-Programmable Gate Array (FPGA).

The third power receiving group 3 includes a power receiving end B2, a plurality of chargers and dischargers 30, a power meter 60 and a control device 70.

The power receiving end B2 converts the power supplied from the power receiving end A into a predetermined voltage, and supplies the converted power to the plurality of chargers and dischargers 30. The power receiving end B2 is configured using a transformer or the like.

The power meter 60 measures the charge and discharge of the power receiving end B2, and outputs the measurement result to the control device 70.

The control device 70 controls the charging and discharging of the third power receiving group 3 under the control of the maintenance and inspection apparatus 10. The control device 70 is implemented using a memory and a processor having hardware. The hardware may be, for example, memories, a CPU, a DSP and an FPGA.

The virtual power plant to which the maintenance and inspection system 100 configured in this manner is applied is a system capable of adjusting the supply-demand balance of the electric power in the distribution network by controlling the charging and discharging operation of the battery installed in the electric vehicle 200. According to such a virtual power plant, by effectively utilizing the power of the batteries use in the electric vehicle 200 to reduce the consumption of fossil fuels in the power plant, it is possible to reduce the generation of CO2 as well as the social costs such as fuel cost, facility cost, and carbon tax. Furthermore, the maintenance and inspection system 100 controls such that the discharged power at the power receiving end B1 and the received power at the power receiving end B2 are equal, and the charging and discharging at the power receiving end A are 0.

Functional configuration of the maintenance equipment

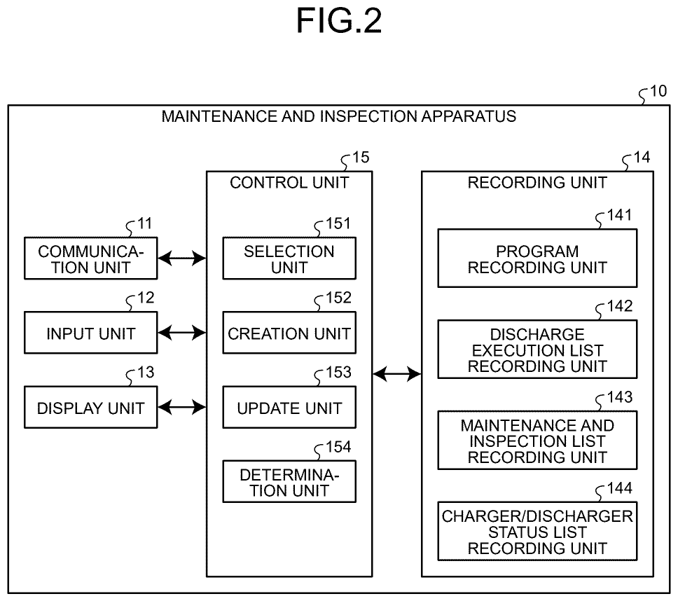

Next, the functional configuration of the maintenance and inspection apparatus 10 is described. FIG. 2 is a block diagram illustrating a functional configuration of the maintenance and inspection apparatus 10.

The maintenance and inspection apparatus 10 illustrated in FIG. 2 includes a communication unit 11, an input unit 12, a display unit 13, a recording unit 14, and a control unit 15.

The communication unit 11 under the control of the control unit 15, via a network (not shown), transmits various information to each of the control device 50 of the second power receiving group 2 and the control device 70 of the third power receiving group 3, and receives various information such as the discharge charge amount from each of the control device 50 of the second power receiving group 2 and the control device 70 of the third power receiving group 3. Further, the communication unit 11 outputs the charged/discharged power measured at the power receiving end A input from the power meter 20 to the control unit 15. The communication unit 11 is configured by using a communication module.

The input unit 12 receives various inputs and outputs them to the control unit 15 in response to an external operation. The input unit 12 is configured by using a button, a keyboard, a switch, a touch panel, or the like.

The display unit 13, under the control of the control unit 15, displays various information related to the maintenance and inspection apparatus 10. The display unit 13 is constituted by using a liquid crystal display or an organic EL display (Organic Electroluminescent Display) or the like.

The recording unit 14 is configured using a Hard Disk Drive (HDD) and a Solid State Drive (SSD). The recording unit 14 includes a program recording unit 141, a discharge execution list recording unit 142, a maintenance and inspection list recording unit 143, and a charger/discharger status list recording unit 144.

The program recording unit 141 records various programs executed by the maintenance and inspection apparatus 10 and various data being executed by the maintenance and inspection apparatus 10.

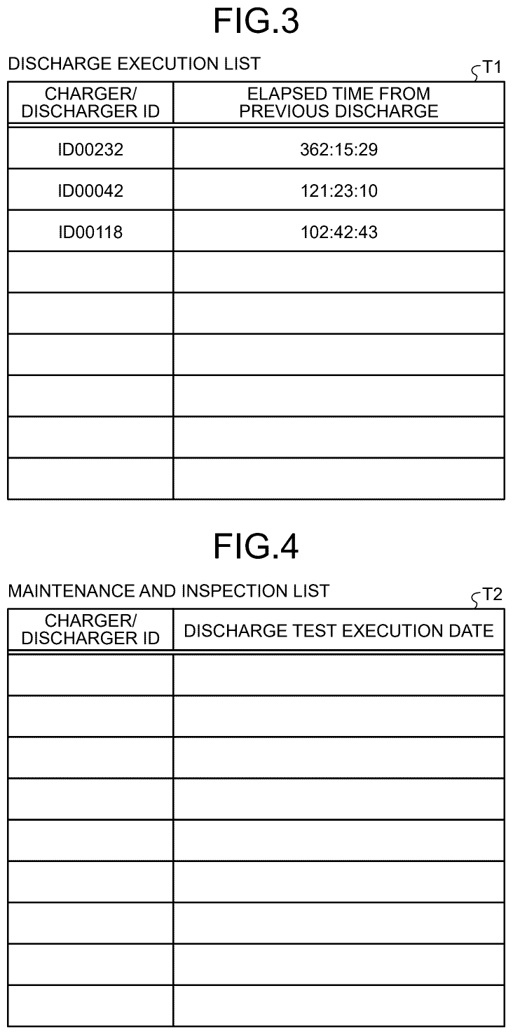

The discharge execution list recording unit 142 records the discharge execution list in which the elapsed time from the previous discharge is associated with each charger/discharger ID for identifying the charger/discharger. FIG. 3 is a diagram illustrating an example of a discharge execution list recorded by the discharge execution list recording unit 142. The discharge execution listing T1 illustrated in FIG. 3, for each charger-discharger ID, is recorded in association with the elapsed time since the previous discharge. For example, the discharge execution listing T1 is recorded in association with the charger/discharger ID“ID00232 with the elapsed time “362:15:29” since the previous discharge. Furthermore, the discharge execution list T1 are recorded side by side in order of elapsed times from the previous discharge.

The maintenance and inspection list recording unit 143 records the maintenance and inspection list corresponding to discharge test execution date for each charger/discharger ID that identifies the charger/discharger. FIG. 4 is a diagram illustrating an example of a maintenance and inspection list recorded by the maintenance and inspection list recording unit 143. In the maintenance and inspection list T2 illustrated in FIG. 4, discharge test execution dates are recorded for each charger/discharger ID in association with each other. In the maintenance and inspection list T2 illustrated in FIG. 4, the charger/discharger is not set for the maintenance and inspection.

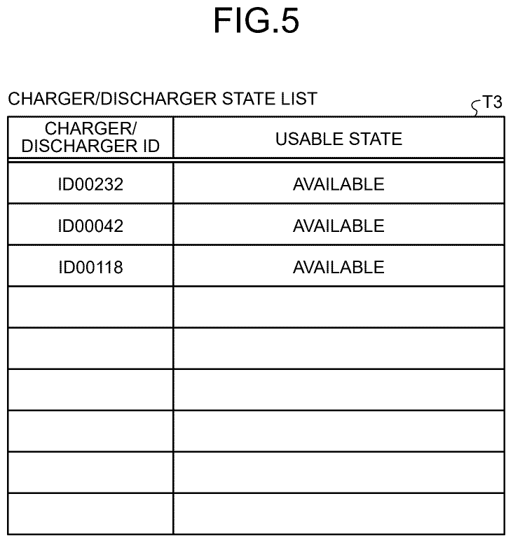

The charger/discharger state list recording unit 144 records the charger/discharger status list in which an available status is associated with each charger/discharger ID that identifies the charger/discharger. FIG. 5 is a diagram illustrating an example of the charger/discharger state list recorded by the charger/discharger state list recording unit 144. In the charger/discharger state list T3 illustrated in FIG. 5, the charger/discharger status is recorded in association with each charger/discharger ID. For example, in the charger/discharger state list T3, the charger/discharger status “available” is recorded in association with the charger/discharger ID“ID00232.

The control unit 15 corresponds to a processor according to the present disclosure. The controller 15 is implemented using a processor having hardware, such as an FPGA, a GPU or a CPU, and memories that are temporary storage used by the processor. The control unit 15 includes a selection unit 151, a creation unit 152, an update unit 153, and a determination unit 154. In one embodiment, the control unit 15 functions as a processor.

The selection unit 151 refers to the discharge execution list T1 stored by the discharge execution list recording unit 142 and the charge/discharge status list T3 recorded by the charge/discharge unit status list recording unit 144 and selects the charge/discharge unit 30 that has the longest time elapsed since the previous discharge execution.

The creation unit 152 creates a test discharge plan with respect to the charge and discharge device 30 of the test discharge object.

The update unit 153, with respect to the charger-discharger 30 to be discharged for test, sets the elapsed time from the previous discharge of the discharge execution list T1 to zero, and updates to move to the end of the discharge execution list T1. Further, when there is an error such as a failure in the charger/discharger 30 to be discharged for inspection, the update unit 153 adds it to the maintenance and inspection list T2 and changes the state in the charger/discharger state list T3 to be unavailable to update the state.

The determination unit 154 determines whether or not a predetermined time, which is the maintenance execution period, has elapsed in the charger/discharger selected by the selection unit 151.

### Process Performed by the Maintenance Equipment

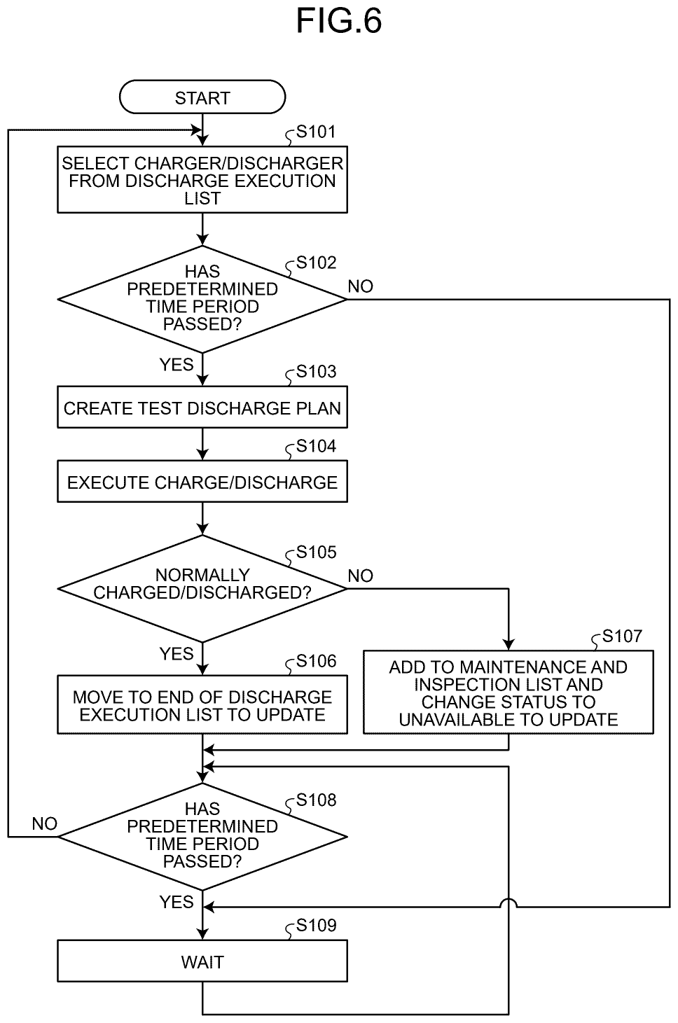

Next, a process that the maintenance and inspection apparatus 10 executes is described. FIG. 6 is a flowchart illustrating an outline of a process that is executed by the maintenance and inspection apparatus 10.

As illustrated in FIG. 6, the selection unit 151 refers to the discharge execution list T1 stored by the discharge execution list recording unit 142 and the charger/discharger state list T3 recorded by the charger/discharger status list recording unit 144, and selects the charger/discharger 30 that has the longest time elapsed since the previous discharge execution in order to check whether there is a charger/discharger 30 that needs to perform a test discharge for maintenance purposes (step S101). Specifically, the selection unit 151, based on the discharge execution list T1 stored by the discharge execution list recording unit 142 (see FIG. 3) and the charger/discharger state list T3 recorded by the charger/discharger status list recording unit 144 (see FIG. 5), in order of longer elapsed time from the previous discharge execution, investigates the charging/discharging unit 30 of the test candidate, the target predetermined period elapsed (for example, 300 hours or more), and, when the charge/discharge state is available, selects the charger/discharger 30 as a test target. In this case, the selection unit 151, as illustrated in the discharge execution list T1 and the charger/discharger state list T3, since the time elapsed from the previous discharge of the charger/discharger ID“ID00232 30 has elapsed a predetermined time, and the available state is “available”, the charger/discharger 30 of the charger/discharger ID“ID00232” is selected as the charger/discharger 30 that needs to be tested for the maintenance purposes. The selection unit 151 excludes the charger/discharger 30 of the charger/discharger ID whose available state is “unavailable” from the selection target of the testing target (to be inspected) based on the charger-discharger state list T3.

The determination unit 154 determines whether the charger/discharger selected by the selection unit 151 has elapsed the predetermined time which is the maintenance implementation period (step S102). In this case, the determination unit 154 determines whether the determined time, for example 300 hours, has elapsed from the previous discharge implementation of the charger and discharger 30 selected by the selection unit 151. When the charging/discharging unit 30 selected by the selection unit 151 by the determination unit 154 is determined to have elapsed for the predetermined time (step S102: Yes), the maintenance and inspection apparatus 10 proceeds to step S103 to be described later. When the determination unit 154 determines that the predetermined time has not elapsed with respect to the charging/discharging unit 30 selected by the selection unit 151 (step S102: No), the maintenance and inspection apparatus 10 proceeds to step S109 to be described later.

In step S103, the creation unit 152 creates a test discharge plan with respect to the charge-discharge device 30 to be tested. In this case, the creation unit 152 selects the electric vehicle 200 for charging the discharged power for testing. The electric vehicle 200 for charging the discharged power for this test is, for example, an electric vehicle 200 in a state of being connected to the charger-discharger 30. The electric vehicle 200 may automatically move to the second power receiving group 2 or the third group and be connected to the charger/discharger 30 according to an instruction signal by the maintenance and inspection apparatus 10.

Subsequently, the update unit 153 performs charging and discharging for the test according to the test discharging plan created by the creation unit 152 (step S104). In this case, the update unit 153 controls each of the control device 50 of the second power receiving group 2 and the control device 50 of the third power receiving group 3 to cause discharge/charge the chargers and dischargers 30 to be inspected of the second power receiving group 2 and the third power receiving group 3 to charge/discharge. At this time, the update unit 153 performs the charging/discharging in the setting such that the discharging amount of the power receiving end B1 and the charging amount of the power receiving end B2 are equal so that there is no power variation at the power receiving end A, considering that the discharging for testing does not affect the power system.

Thereafter, the update unit 153, based on the measurement obtained through the power meter 20, determines whether normally charged and discharged (step S105). Specifically, based on the measurement result acquired through the power meter 20, it is determined whether the power variation at the power receiving end A has occurred. If the power variation does not occur, it is determined that normal charging and discharging has been performed, and if the power variation at the power receiving end A has occurred, it is determined that normal charging and discharging has not been performed. When it is determined that the normal charging and discharging have been performed by the update unit 153 (step S105: Yes), the maintenance and inspection apparatus 10 proceeds to step S106 to be described later. In contrast, when it is determined that the normal charging and discharging are not performed by the update unit 153 (step S105: No), the maintenance and inspection apparatus 10 proceeds to step S107 to be described later.

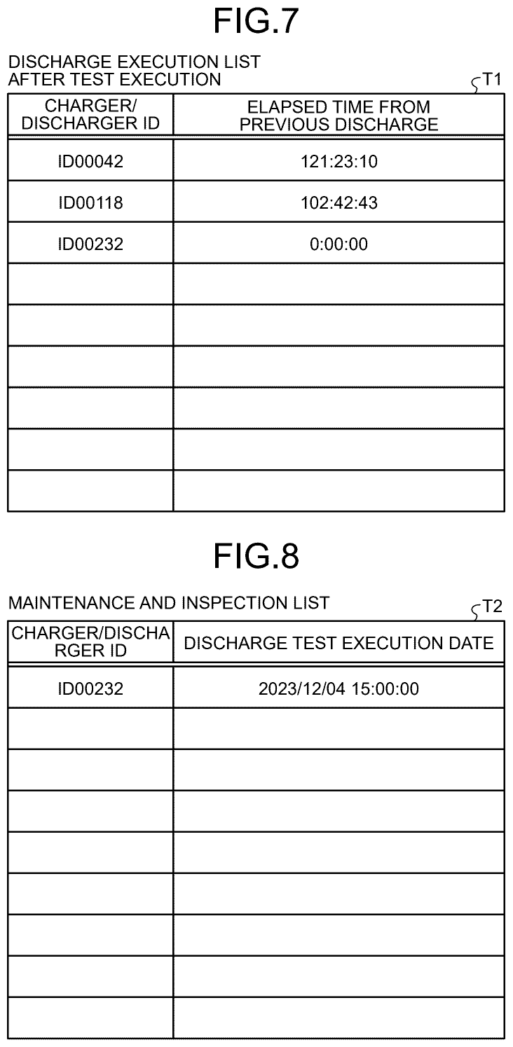

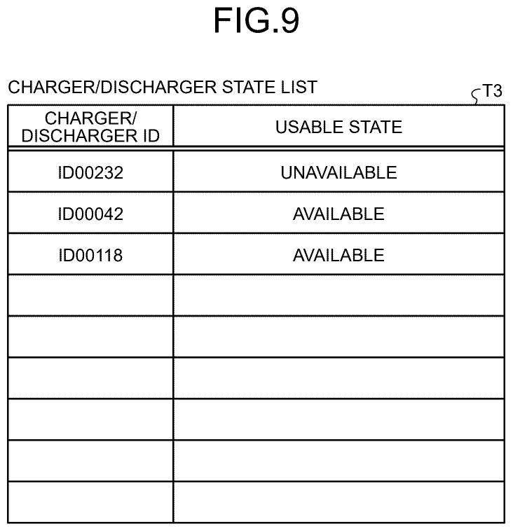

At step S106, the update unit 153, with respect to the charger-discharger 30 to be tested discharge, sets the elapsed time from the previous discharge of the discharge execution list T1 to zero, and updates by moving the data to the end of the discharge execution list T1. FIG. 7 is a diagram illustrating an exemplary discharge execution list T1 after updating. As illustrated in FIG. 7, the update unit 153 moves the charger/discharger ID“ID00232” to the end of the discharge execution list T1 and updates the elapsed time from the previous discharge to zero (0:00:00). After step S106, the maintenance and inspection apparatus 10 proceeds to step S108 described later.

In the stepped S107, the update unit 153 determines that there is an error (abnormality) such as a failure in the charger/discharger 30 to be inspected, adds it to the maintenance and inspection list T2, and changes the state of the charger-discharger state list T3 to be unavailable for updating. Specifically, the update unit 153, in order to make the charger/discharger 30 not subject to VPP, associates the charger/discharger ID“ID00232, in which there is an error such as a failure in the maintenance and inspection list T2, with the discharge test execution date “2023 Dec. 4 15:00:00” and added them. Furthermore, the update unit 153 changes the available state of the charger/discharger ID“ID00232 of the charger/discharger status list T3 to “unavailable” to update it. Thus, the unavailable charger/discharger 30 is not subject to VPP. After step S107, the maintenance and inspection apparatus 10 proceeds to step S108 described later.

In step S108, the selection unit 151 determines whether a predetermined period of time, which is the next implementation timing, has elapsed. If it is determined that the predetermined time has elapsed by the selection unit 151 (step S108: Yes), the maintenance and inspection apparatus 10 returns to step S101. In contrast, if it is determined that the predetermined time has not elapsed by the selection unit 151 (step S108: No), the maintenance and inspection apparatus 10 waits until the predetermined time has elapsed (step S109), the flow returns to the step S108.

According to the embodiment described above, since the selection unit 151 refers to the discharge execution list T1 and the charger-discharger state list T3 to check whether there is a charger/discharger 30 that needs to perform a test discharge for maintenance purposes, since selecting the charger/discharger 30 having the longest time elapsed from the previous discharge execution, it is possible to reliably perform maintenance inspection for a predetermined period.

### Modified Example

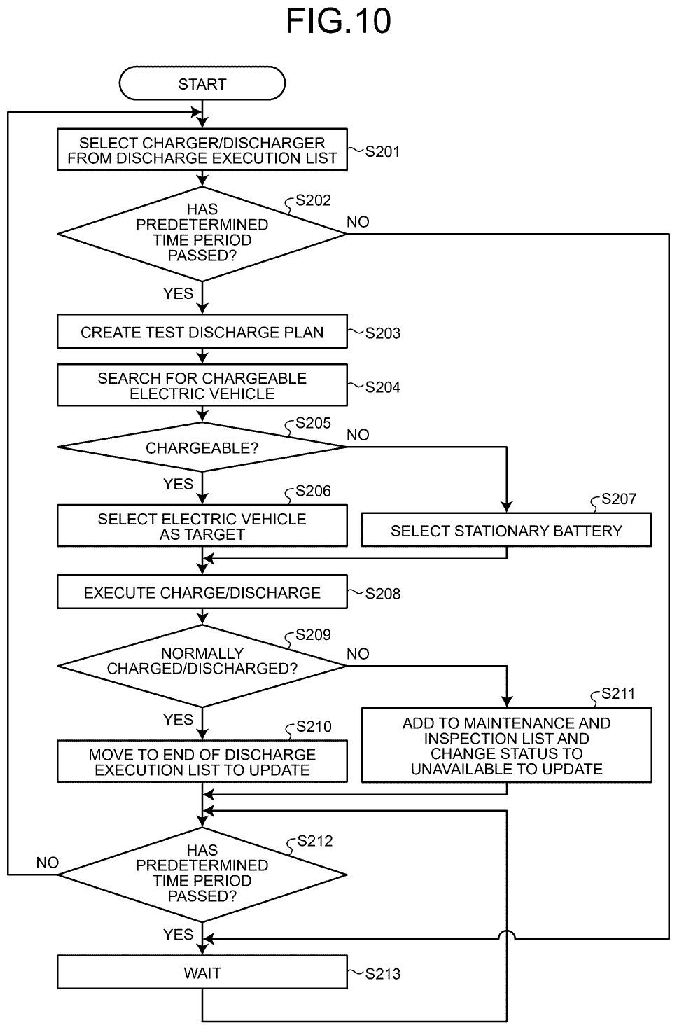

FIG. 10 is a flowchart for explaining an outline of a process that the maintenance and inspection apparatus 10 according to a modified example of an embodiment executes. In FIG. 10, the step S201 to step $203 and step $208 to step S213 correspond to each of the step S101 to step S103 and step S104 to step S109 in FIG. 6, and the process from step S204 to step S103 differs. In the following, the step S204 to step S207 will be described.

In step S204, the creation unit 152 communicates with the control device 50 of the second power receiving group 2 and the control device 70 of the third group to search for the electric vehicle 200 that can be charged. Specifically, the creation unit 152 searches whether the electric vehicle 200 is charging or discharging in any of the charger/discharger 30 of the second power receiving group 2 and the charger/discharger 30 of the third power receiving group 3.

Subsequently, the creation unit 152 determines whether the searched electric vehicle 200 can be discharged (step S205). When the searched electric vehicle 200 can be discharged (step S205: Yes), the searched electric vehicle 200 is selected as the charging target (step S206). After step S206, the maintenance and inspection apparatus 10 proceeds to step S208. In contrast, when the searched electric vehicle 200 cannot be discharged (step S205: No), the creation unit 152 selects the test storage battery (step S207). Specifically, the creation unit 152 selects the stationary battery 31 for discharge of the test discharge plan. After step S207, the maintenance and inspection apparatus 10 proceeds to step S208.

According to a modified example of the embodiment described above, when the searched electric vehicle 200 is not dischargeable, the creation unit 152 selects the test storage battery, so that the maintenance inspection can be surely performed for a predetermined period of time.

### Other Embodiments

In the above embodiment, the test discharge is the target. In one embodiment, however, the target of the test (inspection) may also be considered charging side. In the case of using the electric vehicle 200, charging for traveling, whereas carried out on a daily basis, the discharge in consideration of less frequent discharge side was the object of maintenance and inspection, if the state of less charging opportunities is assumed, it is also possible to consider charging as the object of maintenance and inspection.

In addition, in one embodiment, an electric vehicle 200 and a charger/discharger 30 are required to charge a portion of a test discharge plan so as to perform discharging without affecting the system. But an electric vehicle 200 in a state in which discharging is also possible to the test discharge itself (test discharge itself) is required. Considering these conditions, it may be difficult for the maintenance and inspection apparatus 10 to plan preparation itself of the test discharge. In such case, the state of the charger and discharger 30 may be set to inspection impossible and the next subsequent inspection target.

Further, the maintenance and inspection apparatus 10 may set it unavailable and may count the number of times the unavailable determination has occurred. Then, when the number exceeds a certain value, it is added to the maintenance and inspection list T2.

Further, in the above embodiment, as the condition that the maintenance and inspection apparatus 10 performs the execution of test discharge (inspection discharge), the execution of the diagnosis is performed periodically. However, the execution may be performed depending on events. For example, the maintenance and inspection apparatus 10 may be diagnosed to prepare for an anticipated Demand Response (DR) initiation based on previous achievements.

In the above embodiment, as the condition for performing a test discharge as a representative example, the maintenance and inspection apparatus 10 sets the period from the previous discharge implementation is constant. However, the period may be different depending on the model or the like of the charger/discharger 30. For example, the maintenance and inspection apparatus 10 may vary individually the inspection condition and the period in consideration of the model of the charging and discharging unit 30, failure results, conditions depending on the installation location, and the like.

Further, in the above embodiment, the maintenance and inspection apparatus 10 selects one charger and discharger 30 each time as a representative example. However, it is not always necessary to limit to one per once. For example, when a plurality of chargers and dischargers 30 are installed at the same time, the test discharge of a plurality of chargers and dischargers 30 may perform simultaneous test discharge for plural chargers and dischargers 30 depending on conditions. In this case, it be complicated for the maintenance and inspection apparatus 10 to draft the test plan. But as long as the drafting the test plan is possible, it is possible to set many chargers and dischargers 30 as the targets.

Further effects and variations can be readily derived by one skilled in the art. The broader aspects of the disclosure are not limited to the specific details and representative embodiments expressed and described above. Accordingly, various changes may be made without departing from the spirit or scope of the overall inventive concept defined by the appended claims and their equivalents.

While some of the embodiments of the present application have been described in detail based on the drawings, these are illustrative, and it is possible to implement the present disclosure in other forms which are variously modified and improved based on the knowledge of those skilled in the art, starting from the aspects described in the column of the disclosure of the present disclosure.

According to the present disclosure, there is an effect that it is possible to reliably perform the maintenance inspection in a predetermined period.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A maintenance and inspection apparatus for performing maintenance and inspection in VPP, comprising a processor configured to
select a charger/discharger to be maintained and inspected from among a plurality of chargers and dischargers based on a discharge execution list, in which a time elapsed from a previous discharge with respect to each of the chargers and dischargers, and a charger/discharger state list, which indicates an available state for each of the chargers and dischargers, and
update, after charging/discharging by the charger/discharger to be maintained and inspected, updates the discharge execution list by adding an execution result of test charge/discharge by the charger/discharger to be maintained and inspected.

2. The maintenance and inspection apparatus according to claim 1, wherein
the processor is configured to
determine whether the charger/discharger to be maintained and inspected is in a normal state,
update, when the charger/discharger to be maintained and inspected is in the normal state, the discharge execution list by adding the execution result of the test charge/discharge by the charger/discharger to be maintained and inspected, and
when the charger/discharger to be maintained and inspected is not in the normal state, change a state of charger/discharger to be maintained and inspected in the charger/discharger state list to unavailable, and record the charger/discharger to be maintained and inspected and a date of the test charge/discharge in a maintenance and inspection list.

3. The maintenance and inspection apparatus according to claim 2, wherein
the processor is configured to, when an electric vehicle for charging a power to a discharged charger/discharger to be maintained and inspected cannot be selected, charge a power to a stationary battery disposed in a same system as a power receiving end to which the charger/discharger to be maintained and inspected is connected.

4. The maintenance and inspection apparatus according to claim 3, wherein
the processor is configured to perform charging and discharging in a manner that a charge amount and a discharge amount are equal to each other at the power receiving end to which the charger/discharger to be maintained and inspected is connected.
